(19) United States
(12) Patent Application Publication
(10) Pub. No.: US 2013/0106418 A1
(43) Pub. Date: May 2, 2013

(54) HEAT CONDUCTING COMPONENT AND MANUFACTURING METHOD THEREFOR AND REFRIGERATION SYSTEM AND MAGNETIC RESONANCE IMAGING EQUIPMENT EMPLOYING SUCH A COMPONENT

(71) Applicants: Ji Ming Chen, Shenzhen (CN); Zhi Chun Fang, Nanshan, P.R. China (CN)

(72) Inventors: Ji Ming Chen, Shenzhen (CN); Zhi Chun Fang, Nanshan, P.R. China (CN)

(21) Appl. No.: 13/664,553

(22) Filed: Oct. 31, 2012

(30) Foreign Application Priority Data
Oct. 31, 2011 (DE) 201110336630.2

(51) Int. Cl. G01R 33/383; B21D 53/02; B23P 11/00; F28F 21/08

(52) U.S. Cl. 324/319; 165/185; 29/890.043; 29/525.14

(57) ABSTRACT

In a heat conducting component used in a superconducting magnet refrigeration system and a manufacturing method for the same, a superconducting magnet refrigeration system and magnetic resonance imaging equipment, the heat conducting component includes an aluminum block, annular stainless steel transition part, and a first thin wall tube, wherein there is a through-hole in the aluminum block. The stainless steel transition part is friction welded at one end thereof to one end face of the aluminum block, and has an annular step at that end thereof which is remote from the aluminum block. One end of the thin wall tube is welded to the annular step of the stainless steel transition part.

### BACKGROUND OF THE INVENTION

1. Field of the Invention

The present invention relates to a refrigeration system for a superconducting magnet, in particular to a heat conducting component used in a superconducting magnet refrigeration system as well as a manufacturing method for such a components and, a superconducting magnet refrigeration system and magnetic resonance imaging equipment that make use of such a component.

2. Description of the Prior Art

In a typical superconducting magnet refrigeration system for cooling a superconducting magnet, such as a superconducting magnet refrigeration system in magnetic resonance imaging (MRI) equipment, the superconducting magnet is generally placed in a cryogen vessel which is in turn placed in an external vacuum chamber; the space between the vacuum chamber and the cryogen vessel is evacuated so as to provide effective heat insulation for the cryogen vessel. However, owing to the relatively large temperature difference between the outside of the vacuum chamber and the interior of the cryogen vessel, there is significant radiation of heat between the vacuum chamber and the cryogen vessel; in order to reduce the amount of heat radiation between the vacuum chamber and the cryogen vessel, a heat radiation shield is generally provided between the vacuum chamber and the cryogen vessel.

In any one of several known alternative refrigeration methods, a superconducting magnet is generally cooled to a predetermined temperature, i.e. the operating temperature, by causing a liquid refrigerant (such as liquid helium) to boil and vaporize. In order to reduce consumption of refrigerant and the speed of vaporization, and allow magnet cooling to be maintained for a longer time before it is necessary to replenish the refrigerant, a refrigerator is generally provided which is capable of performing cooling below the boiling point of the refrigerant, so that not only is the heat radiation shield cooled, but also at least some of the vaporized refrigerant vapor condenses back to liquid form.

Such a refrigerator generally uses a cold head to provide cold, using a heat conducting component to transfer the cold provided by the cold head to the heat radiation shield and refrigerant vapor.

### SUMMARY OF THE INVENTION

An object of the present invention is to provide a heat conducting component for use in a superconducting magnet refrigeration system and a manufacturing method for such a component, by means of which the cost of raw materials for the heat conducting component and the production thereof may be reduced. A further object of the present invention is to provide a superconducting magnet refrigeration system and magnetic resonance imaging equipment embodying such a component.

This object is achieved in accordance with the present invention by a heat conducting component used in a superconducting magnet refrigeration system, including: an aluminum block, an annular stainless steel transition part, and a thin wall tube, wherein the aluminum block has a through-hole therein, the stainless steel transition part is friction welded at one end thereof to one end face of the aluminum block, and has an annular step at the end thereof that is remote from the aluminum block, and one end of the thin wall tube is welded to the annular step of the stainless steel transition part.

Optionally, one end of the thin wall tube is welded to the annular step of the stainless steel transition part by argon arc welding.

Optionally, the heat conducting component further has an annular second stainless steel transition part and a second thin wall tube, the second stainless steel transition part being friction welded at one end thereof to another end face of the aluminum block, and having an annular step at the end thereof that is remote from the aluminum block, and one end of the second thin wall tube is welded to the annular step of the second stainless steel transition part.

Optionally, one end of the second thin wall tube is welded to the annular step of the second stainless steel transition part by argon arc welding.

Optionally, the heat conducting component further includes copper braid, including two aluminum terminals, one terminal being connected to the aluminum block by a screw and/or welding, and the other terminal being connected to a thermal radiation shielding part of a superconducting magnet refrigeration system by a screw and/or welding.

The present invention also provides a superconducting magnet refrigeration system, including a cold head, and further including the heat conducting component as described above, wherein the through-hole of the aluminum block fits and receives the cold head.

Optionally, the heat conducting component also includes a thermal radiation shielding part, and the other terminal of the copper braid is connected to the thermal radiation shielding part by a screw and/or welding.

The present invention also encompasses magnetic resonance imaging equipment, including the abovementioned superconducting magnet refrigeration system.

The present invention also encompasses a method for manufacturing a heat conducting component used in a superconducting magnet refrigeration system, including:
A. friction welding one end of an annular stainless steel transition part to one end face of an aluminum block;
B. machining an annular step at the end of the stainless steel transition part that is remote from the aluminum block;
C. machining a through-hole fitting a cold head in the aluminum block;
D. welding one end of a stainless steel thin wall tube to the annular step the first stainless steel transition part.

Step A can further include friction welding one end of an annular second stainless steel transition part to another end face of the aluminum block. Step B can further includes machining an annular step at that end of the second stainless steel transition part that is remote from the aluminum block. Step D can further includes welding one end of a second stainless steel thin wall tube to the annular step of the second stainless steel transition part.

Before the step of friction welding one end of an annular stainless steel transition part to one end face of an aluminum block, the method can further include machining an annular conical locating groove with a wedge cross section at one end face of the aluminum block, and machining one end tube wall of the annular stainless steel transition part into an annular conical locating pin with a wedge-shaped cross-section. The step of friction welding one end of an annular stainless steel transition part to one end face of an aluminum block can be implemented by placing the annular conical locating pin of the stainless steel transition part into the first annular conical locating groove of the aluminum block, and performing friction welding.

Optionally, before the step of friction welding one end of an annular second stainless steel transition part to another end face of the aluminum block, the method further can include machining a second annular conical locating groove with a wedge-shaped cross-section at another end face of the aluminum block, and machining one end tube wall of the annular second stainless steel transition part into a second annular conical locating pin with a wedge-shaped cross-section. The step of friction welding one end of an annular second stainless steel transition part to another end face of an aluminum block can be implemented by placing the second annular conical locating pin of the second stainless steel transition part into the second annular conical locating groove of the aluminum block, and performing friction welding.

Optionally, the method further includes pressure welding one aluminum terminal separately at two ends of copper braid; connecting one terminal of the copper braid to the aluminum block by a screw and/or welding, and connecting the other terminal of the copper braid to a thermal radiation shielding part of a superconducting magnet refrigeration system by a screw and/or welding.

It is evident from the above solution that the use in the present invention of an aluminum block in place of the copper block used in traditional heat conducting components allows raw material costs and the weight of the heat conducting component to be reduced. Furthermore, replacing the vacuum brazing used for traditional heat conducting components with friction welding enables the welding cycle to be shortened, and hence the manufacturing costs to be reduced. Moreover, as a result of additionally providing a stainless steel transition part between the aluminum block and the stainless steel thin wall tube, the welds will not be affected by deformation of the stainless steel thin wall tube, so that an excellent quality of weld is achieved.

Further, as a result of machining an annular conical locating groove on the aluminum block and an annular conical locating pin on the stainless steel transition part before friction welding the stainless steel transition part to the aluminum block, the two can be located better, and friction welding is convenient.

Further, in the present invention, convenient and simple argon arc welding may be employed to weld one end of the first stainless steel thin wall tube to the annular step of said first stainless steel transition part, thereby simplifying the manufacturing process of the heat conducting component.

In addition, replacing the copper terminals of traditional copper braid with aluminum terminals allows Al-aluminum connections to be formed between the copper braid and the aluminum block, and between the copper braid and the thermal radiation shielding part, reducing the thermal contact resistance therebetween and improving the heat conducting ability.

### BRIEF DESCRIPTION OF THE DRAWINGS

FIG. 1 is a schematic diagram of a portion of a known heat conducting component in current use.

FIG. 2 is a flow chart of the method for manufacturing a heat conducting component used in a superconducting magnet refrigeration system in an embodiment of the present invention.

FIGS. 3a to 3c are structural schematic diagrams of the friction welding of one end of an annular outside stainless steel transition part to one end face of an aluminum block.

FIGS. 4a to 4c are structural schematic diagrams of the machining of an annular step at that end of the outside stainless steel transition part shown in FIG. 3a that is remote from the aluminum block, and the machining of a through-hole in the aluminum block shown in FIGS. 3a to 3c.

FIGS. 5a to 5c are structural schematic diagrams in which an outside stainless steel thin wall tube has been welded using argon arc welding to the annular step of the outside stainless steel transition part shown in FIGS. 4a to 4c.

### DESCRIPTION OF THE PREFERRED EMBODIMENTS

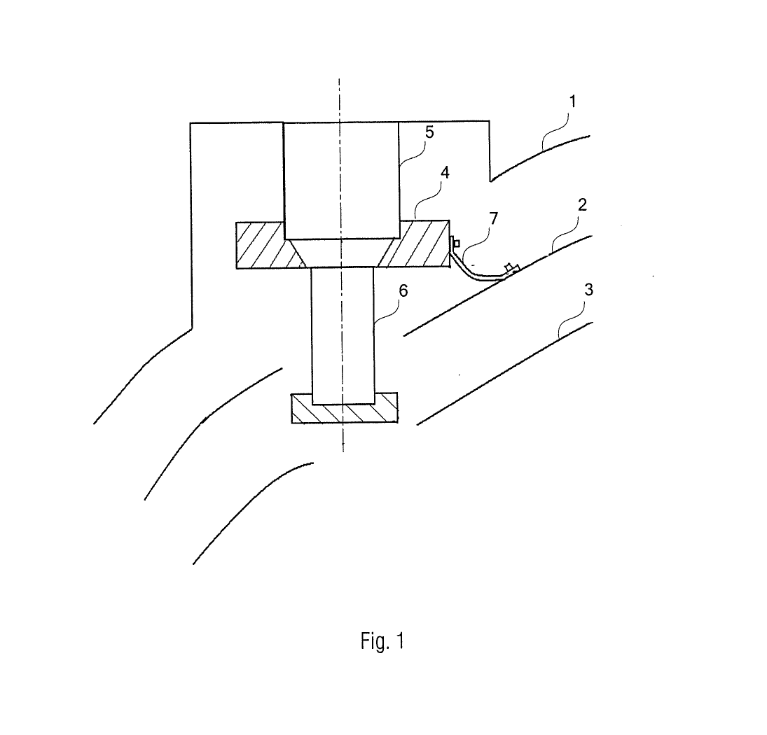

FIG. 1 shows a partial structural schematic diagram of a known heat conducting component in current use. As FIG. 1 shows, the heat conducting component is in communication with a cryogen vessel 3 after passing through a vacuum chamber 1, a thermal radiation shielding part 2 and a side wall of the cryogen vessel 3. The heat conducting component includes a copper block 4 having a tapered through-hole fitting a cold head, an outside stainless steel thin wall tube 5 and an inside stainless steel thin wall tube 6 welded to two sides of the copper block 4, respectively, by vacuum brazing, and copper braid 7 separately connected to the copper block 4 and to the thermal radiation shielding part 2 by way of two copper terminals. The cold head is fitted to the heat conducting component by way of the outside stainless steel thin wall tube 5 and the through-hole of the copper block 4. Cold provided by the cold head is conducted on the one hand to the thermal radiation shielding part 2 through the copper block 4 and copper braid 7, achieving cooling of the thermal radiation shielding part 2, and on the other is transferred to cryogen vapor via the inside stainless steel thin wall tube 6 and other components, causing the cryogen vapor to condense back to liquid form.

In the above heat conducting component, although the copper block 4 has relatively good heat conducting properties, it is quite expensive. Moreover, although the vacuum brazing used to weld the copper block 4 to the two stainless steel thin wall tubes joins metals quite well, it takes quite a long time, generally 16 hours, and with initial preparation taken into account, the manufacturing cycle when vacuum brazing is used is generally 20 hours or more. As a result, this currently used heat conducting component has relatively high raw material and manufacturing costs.

In the present invention, the above copper block 4 is replaced with an aluminum block; in this way, not only can the cost of raw materials for the heat conducting component be reduced, but the weight of the heat conducting component can also be reduced. Moreover, by replacing the abovementioned vacuum brazing between copper and stainless steel with friction welding between aluminum and stainless steel, the welding cycle can be greatly shortened, reducing the cost of manufacturing the heat conducting component. Furthermore, in the present invention, an annular stainless steel transition part is additionally provided between the aluminum block and the stainless steel thin wall tube; in this way, the problem of deformation which readily occurs when a stainless steel thin wall tube is friction welded directly to an aluminum block can be avoided.

During actual application, an annular outside stainless steel transition part can be added between the aluminum block and the outside stainless steel thin wall tube, with an annular inside stainless steel transition part being added between the aluminum block and the inside stainless steel thin wall tube at the same time. It is also possible to only add an annular outside stainless steel transition part between the aluminum block and the outside stainless steel thin wall tube, while welding may still be carried out between the aluminum block and the inside stainless steel thin wall tube using vacuum welding, friction welding or another method. Alternatively, it is also possible to only add an annular inside stainless steel transition part between the aluminum block and the inside stainless steel thin wall tube, while welding may still be carried out between the aluminum block and the outside stainless steel thin wall tube using vacuum brazing, friction welding or another method.

In order to make the object, technical solution and advantages of the present invention clearer, the present invention will be described in further detail below by way of examples.

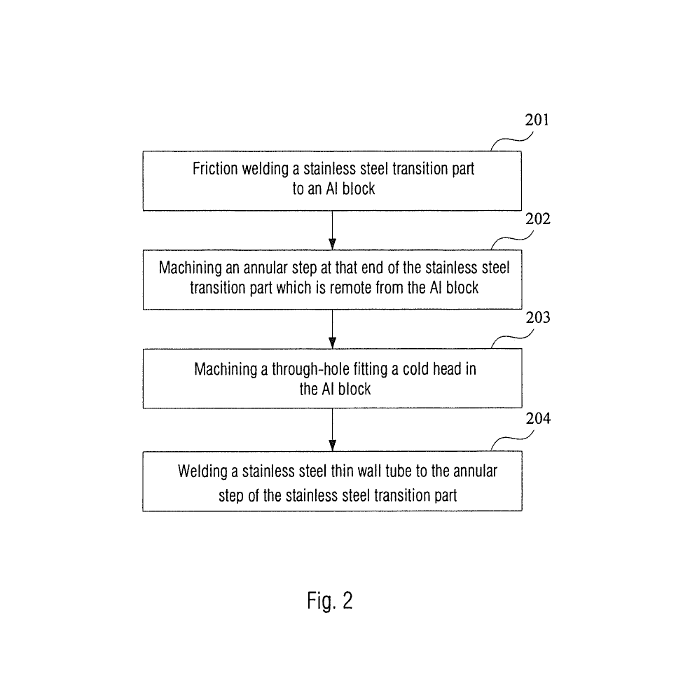

FIG. 2 is a flow chart of the manufacturing method for a heat conducting component used in a superconducting magnet refrigeration system in an embodiment of the present invention.

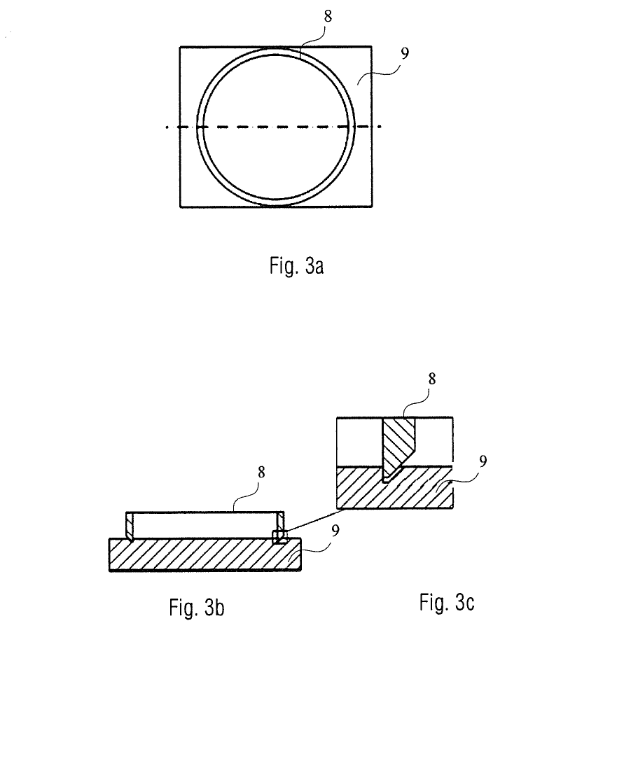

FIGS. 3a to 5c are exemplary process structural diagrams corresponding to the manufacturing method shown in FIG. 2, in which the case of an outside stainless steel transition part being additionally provided between the aluminum block and the outside stainless steel thin wall tube is taken as an example.

As shown in FIG. 2, the method includes the following steps: Step 201, friction welding one end of an annular first stainless steel transition part to one end face of an aluminum block. The inner diameter of the first stainless steel transition part is less than that of a first stainless steel thin wall tube, and the outer diameter of the first stainless steel transition part is greater than that of the first stainless steel thin wall tube.

FIGS. 3a to 3c are structural schematic diagrams of the friction welding of one end of an annular outside stainless steel transition part 8 to one end face of an aluminum block 9. FIG. 3a is a view from above, FIG. 3b is a sectional drawing of a main view, and FIG. 3c is a magnified drawing of part of FIG. 3b.

During particular implementation, a first annular conical locating groove with a wedge-shaped cross-section may be machined at one end face of said aluminum block first, with one end tube wall of said annular first stainless steel transition part being machined into a first annular conical locating pin with a wedge-shaped cross-section; then, the first annular conical locating pin of said first stainless steel transition part is placed into the first annular conical locating groove of the aluminum block, and friction welding is carried out. The first annular conical locating groove may have a depth of 2 mm, 3 mm, or 4 mm, etc.

Friction welding is capable of eliminating intermetallic compounds created between aluminum and stainless steel by ordinary welding, enabling the welding region between the two to achieve the strength of aluminum. Furthermore, the welding cycle when using friction welding can be shortened to less than 1 minute.

Step 202, machining an annular step at that end of said first stainless steel transition part which is remote from said aluminum block.

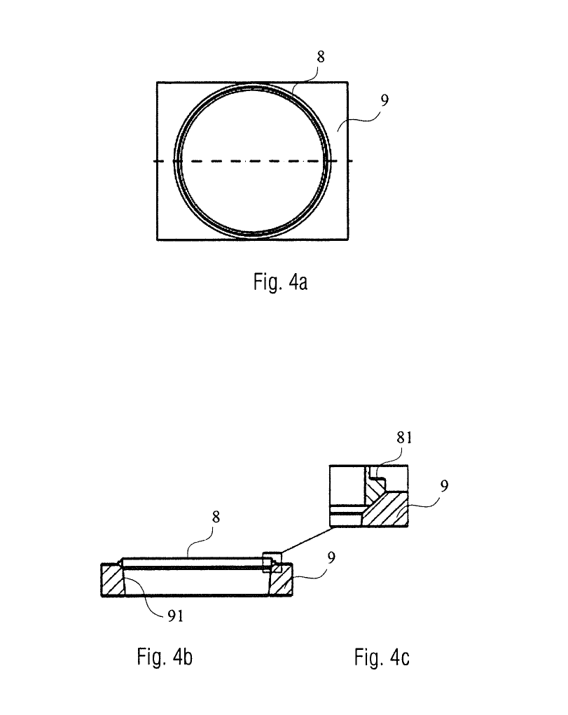

FIGS. 4a to 4c are structural schematic diagrams of the machining of an annular step 81 at that end of the outside stainless steel transition part 8 shown in FIGS. 3a to 3c which is remote from said aluminum block 9. FIG. 4a is a view from above, FIG. 4b is a sectional drawing of a main view, and FIG. 4c is a magnified drawing of part of FIG. 4b.

During particular implementation, in order to facilitate chucking during the friction welding process, the first stainless steel transition part may be set to be slightly longer; once friction welding is complete, the excess portion of the first stainless steel transition part can be cut away, and an annular step can then be machined on the end face left after cutting.

Step 203, machining a through-hole fitting a cold head in the aluminum block.

FIGS. 4a to 4c are also structural schematic diagrams showing the machining of a through-hole, that is, a conical through-hole 91, in the aluminum block 9 shown in FIGS. 3a to 3c.

In this embodiment, since there is no need to machine a through-hole prior to friction welding, as is necessary in the case of vacuum welding, the through-hole in the aluminum block may be machined afterwards in this step; thus the through-hole may be machined to a suitable angle and size directly, with no need to take into account deformation caused by heat treatment or to perform secondary machining of the through-hole after welding is complete, as is necessary in the case of vacuum welding.

Step 204, welding one end of a first stainless steel thin wall tube to the annular step of the first stainless steel transition part.

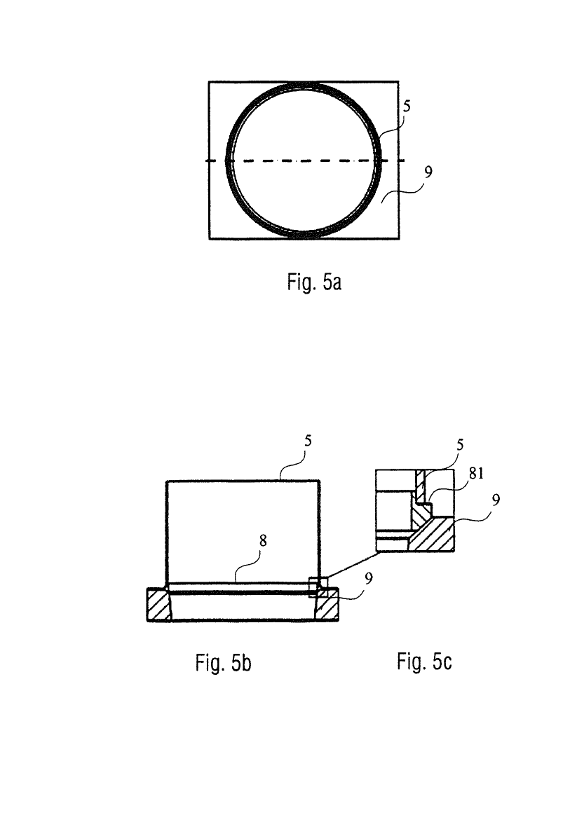

FIGS. 5a to 5c are structural schematic diagrams in which an outside stainless steel thin wall tube 5 has been welded to the annular step of the outside stainless steel transition part 8 shown in FIGS. 4a to 4c. FIG. 5a is a view from above, FIG. 5b is a sectional drawing of a main view, and FIG. 5c is a magnified drawing of part of FIG. 5b.

During particular implementation, welding can be performed using argon arc welding or another method of welding, and fillet welding may also be used. When argon arc welding is used in this embodiment, the welding method is simple and easy.

The first stainless steel thin wall tube may be an outside stainless steel thin wall tube or an inside stainless steel thin wall tube; correspondingly, the first stainless steel transition part may be an outside stainless steel transition part or an inside stainless steel transition part.

Further, step 201 may further include: friction welding one end of an annular second stainless steel transition part to another end face of the aluminum block. Step 202 may further include: machining an annular step at that end of said second stainless steel transition part which is remote from the aluminum block. Step 204 may further include: welding one end of a second stainless steel thin wall tube to the annular step of the second stainless steel transition part.

The specific process for the second stainless steel transition part and the second stainless steel thin wall tube may be the same as the specific process described above for the first stainless steel transition part and the first stainless steel thin wall tube, and need not be repeated.

If the first stainless steel thin wall tube is an outside stainless steel thin wall tube, then the second stainless steel thin wall tube is an inside stainless steel thin wall tube, and vice versa; correspondingly, if the first stainless steel transition part is an outside stainless steel transition part, then the second stainless steel transition part is an inside stainless steel transition part, and vice versa.

Furthermore, since the thermal radiation shielding part in a superconducting magnet refrigeration system is generally of aluminum material, while the two terminals of the copper braid in the application shown in FIG. 1 are of copper material, when the terminals of the copper braid are connected to the thermal radiation shielding part, the thermal contact resistance between the two will be quite high, affecting the heat conducting ability between the two.

In the present invention, in order to reduce the thermal resistance between the copper braid and the thermal radiation shielding part, consideration is given to changing the two terminals of the copper braid to aluminum material, that is, the method shown in FIG. 2 may further include: pressure welding one aluminum terminal separately at two ends of copper braid; connecting one terminal of the copper braid to the aluminum block by a screw and/or welding, and connecting the other terminal of said copper braid to a thermal radiation shielding part of the superconducting magnet refrigeration system by screw and/or welding. The method of welding may be argon arc welding. Thus the connections between the two terminals of the copper braid and the aluminum block and the thermal radiation shielding part are both aluminum-to-aluminum connections, so that the thermal contact resistance is lower, improving the heat conducting ability therebetween.

Correspondingly, the embodiments of the present invention also provide a heat conducting component used in a superconducting magnet refrigeration system; the heat conducting component may include: an aluminum block, an annular first stainless steel transition part and a first thin wall tube.

There is a through-hole fitting a cold head in the aluminum block.

The first stainless steel transition part is friction welded at one end thereof to one end face of the aluminum block, and has an annular step at that end thereof which is remote from the aluminum block.

One end of the first thin wall tube is welded to the annular step of the first stainless steel transition part. Argon arc welding may be used to weld one end of the first thin wall tube to the annular step of the first stainless steel transition part.

As in the manufacturing method, the heat conducting component may further include an annular second stainless steel transition part and a second thin wall tube.

The second stainless steel transition part is friction welded at one end thereof to another end face of the aluminum block, and has an annular step at that end thereof which is remote from the aluminum block.

One end of the second thin wall tube is welded to the annular step of the second stainless steel transition part. Similarly, argon arc welding may also be used to weld one end of the second thin wall tube to the annular step of the second stainless steel transition part.

The first stainless steel thin wall tube may be an outside stainless steel thin wall tube or an inside stainless steel thin wall tube; correspondingly, the first stainless steel transition part may be an outside stainless steel transition part or an inside stainless steel transition part.

Moreover, if the first stainless steel thin wall tube is an outside stainless steel thin wall tube, then the second stainless steel thin wall tube is an inside stainless steel thin wall tube, and vice versa; correspondingly, if the first stainless steel transition part is an outside stainless steel transition part, then the second stainless steel transition part is an inside stainless steel transition part, and vice versa.

In addition, the heat conducting component in the present invention may further include a copper braid having two aluminum terminals. One terminal of the copper braid is connected to the aluminum block by a screw and/or welding, and the other terminal is connected to a thermal radiation shielding part of the superconducting magnet refrigeration system by a screw and/or welding.

The superconducting magnet refrigeration system of the present application includes a cold head, and also includes a heat conducting component as described above, wherein the through-hole of the aluminum block fits the cold head.

The superconducting magnet refrigeration system may also include a thermal radiation shielding part. The other terminal of said copper braid is connected to the thermal radiation shielding part by screw and/or welding.

The magnetic resonance imaging equipment of the present application includes the superconducting magnet refrigeration system described above.

Disclosed in the present invention are a heat conducting component used in a superconducting magnet refrigeration system and a manufacturing method therefor, a superconducting magnet refrigeration system, and magnetic resonance imaging equipment. The heat conducting component includes an aluminum block, an annular first stainless steel transition part and a thin wall tube, wherein there is a through-hole in the aluminum block. The stainless steel transition part is friction welded at one end thereof to one end face of the aluminum block, and has an annular step at the end thereof that is remote from the aluminum block; and one end of the thin wall tube is welded to the annular step of the stainless steel transition part. The present invention can reduce raw material costs and the weight of the heat conducting component, and furthermore can shorten the welding cycle, thereby reducing manufacturing costs.

Although modifications and changes may be suggested by those skilled in the art, it is the intention of the inventor to embody within the patent warranted hereon all changes and modifications as reasonably and properly come within the scope of their contribution to the art.

We claim as our invention:

1. A heat conducting component for a superconducting magnet refrigeration system, comprising:
an aluminum block having a through-hole extending through said aluminum block, said aluminum block having end faces;
a stainless steel transition part friction-welded at one end of said transition part to one end face of said aluminum block, said transition part having an annular step at an opposite end thereof remote from said aluminum block; and
a thin-walled tube welded to said annular step of said stainless steel transition part.

2. A heat conducting component as claimed in claim 1 wherein said thin-walled tube is welded to said annular step of said stainless steel transition part by argon arc welding.

3. A heat conducting component as claimed in claim 1 wherein said annular stainless steel transition part is a first annular stainless steel transition part and wherein said thin-walled tube is a first thin-walled tube, and wherein said heat conducting component further comprises:
an annular second stainless steel transition part, and a second thin-walled tube;
said second stainless steel transition part being friction-welded at one end thereof to another of said end faces of said aluminum block, and having an annular step at an opposite end thereof that is remote from said aluminum block; and
said second thin-walled tube being welded at one end thereof to said annular step of said second stainless steel transition part.

4. A heat conducting component as claimed in claim 3 wherein said second thin-walled tube is welded to said annular step of said second stainless steel transition part by argon arc welding.

5. A heat conducting component as claimed in claim 1 comprising copper braid having two aluminum terminals, one of said two terminals being connected to said aluminum block by screwing or welding, and a second of said two terminals being connected to a thermal radiation shielding part of a superconducting magnet refrigeration system by screwing or welding.

6. A superconducting magnet refrigeration system, comprising:
a cold head;
an aluminum block having a through-hole extending through said aluminum block, said through-hole being fitted to said cold head, said aluminum block having end faces;
a stainless steel transition part friction-welded at one end of said transition part to one end face of said aluminum block, said transition part having an annular step at an opposite end thereof remote from said aluminum block; and
a thin-walled tube welded to said annular step of said stainless steel transition part.

7. A superconducting magnet refrigeration system as claimed in claim 6, comprising:
a thermal radiation shielding part;
copper braid having two aluminum terminals; and
one of said two aluminum terminals being connected to said aluminum block by screwing or welding, and a second of said two terminals being connected to said thermal radiation shielding part by screwing or welding.

8. A magnetic resonance imaging apparatus comprising:
a magnetic resonance data acquisition unit comprising a basic field magnet having a superconducting magnet refrigeration system comprising a cold head;
an aluminum block having a through-hole extending through said aluminum block, said through-hole being fitted to said cold head, said aluminum block having end faces;
a stainless steel transition part friction-welded at one end of said transition part to one end face of said aluminum block, said transition part having an annular step at an opposite end thereof remote from said aluminum block; and
a thin-walled tube welded to said annular step of said stainless steel transition part.

9. Manufacturing method for a heat conducting component used in a superconducting magnet refrigeration system, comprising:
A. friction welding one end of one annular first stainless steel transition part to one end face of one aluminum block;
B. machining an annular step at that end of said first stainless steel transition part which is remote from said aluminum block;
C. machining a through-hole fitting a cold head in said aluminum block;
D. welding one end of a first stainless steel thin wall tube to the annular step of said first stainless steel transition part.

10. Method according to claim 9, wherein
step A further comprises friction welding one end of one annular second stainless steel transition part to another end face of said aluminum block;
step B further comprises machining an annular step at that end of said second stainless steel transition part which is remote from said aluminum block;
step D further comprises welding one end of a second stainless steel thin wall tube to the annular step of said second stainless steel transition part.

11. Method according to claim 9, by further comprising machining a first annular conical locating groove with a wedge cross section at one end face of said aluminum block, machining one end tube wall of said annular first stainless steel transition part into a first annular conical locating pin with a wedge cross section; placing the first annular conical locating pin of said first stainless steel transition part into the first annular conical locating groove of said aluminum block, and performing friction welding.

12. Method according to claim 10, by further comprising machining a second annular conical locating groove with a wedge cross section at another end face of said aluminum block, machining one end tube wall of said annular second stainless steel transition part into a second annular conical locating pin with a wedge cross section; placing the second annular conical locating pin of said second stainless steel transition part into the second annular conical locating groove of said aluminum block, and performing friction welding.

13. A method as claimed in claim 9 further comprising:
pressure welding one aluminum terminal separately at two ends of copper braid;
connecting one terminal of said copper braid to said aluminum block by screw and/or welding, and connecting the other terminal of said copper braid to a thermal radiation shielding part of a superconducting magnet refrigeration system by screw and/or welding.

14. A heat conducting component for a superconducting magnet refrigeration system, comprising:
an aluminum block having end faces;
a stainless steel transition part friction-welded at one end of said transition part to one end face of said aluminum block, said transition part having an annular step at an opposite end thereof remote from said aluminum block; and
a thin-walled tube welded to said annular step of said stainless steel transition part.

15. A superconducting magnet refrigeration system, comprising:
a cold head;
an aluminum block to which said cold head is fitted, said aluminum block having end faces;
a stainless steel transition part friction-welded at one end of said transition part to one end face of said aluminum block, said transition part having an annular step at an opposite end thereof remote from said aluminum block; and
a thin-walled tube welded to said annular step of said stainless steel transition part.

16. A magnetic resonance imaging apparatus comprising:
a magnetic resonance data acquisition unit comprising a basic field magnet having a superconducting magnet refrigeration system comprising a cold head;
an aluminum block to which said cold head is fitted, said aluminum block having end faces;
a stainless steel transition part friction-welded at one end of said transition part to one end face of said aluminum block, said transition part having an annular step at an opposite end thereof remote from said aluminum block; and
a thin-walled tube welded to said annular step of said stainless steel transition part.

17. Manufacturing method for a heat conducting component used in a superconducting magnet refrigeration system, comprising:
A. friction welding one end of one annular first stainless steel transition part to one end face of one aluminum block;
B. machining an annular step at that end of said first stainless steel transition part which is remote from said aluminum block; and
C. welding one end of a first stainless steel thin wall tube to the annular step of said first stainless steel transition part.
